(19) United States
(12) Patent Application Publication
(10) Pub. No.: US 2006/0060924 A1
(43) Pub. Date: Mar. 23, 2006

(54) Field-effect transistor and sensor, and methods of manufacturing the same

(75) Inventors: Miki Ogawa, Tokyo (JP); Hirokatsu Miyata, Hadano-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/227,175

(22) Filed: Sep. 16, 2005

(30) Foreign Application Priority Data
Sep. 17, 2004 (JP) 2004-271804

(51) Int. Cl. H01L 29/76

(52) U.S. Cl. 257/364

(57) ABSTRACT

In order to provide an FET biosensor which enables the highly sensitive detection, the present invention employs a field-effect transistor comprising a source region, a drain region and a gate region, wherein the gate region employs a porous material having mesopores of which the walls contain crystals of tin oxide.

### BACKGROUND OF THE INVENTION

1. Field of the Invention

The present invention relates to a field-effect transistor and a method of manufacturing the same, particularly, to a sensor field-effect transistor to detect a substance by utilizing the gate function through adsorption/desorption of a substance and a method of manufacturing the same. The sensor of the present invention can be suitably used as a gas sensor to detect a gas, a biosensor to detect a biological substance, etc.

2. Related Background Art

Various systems for sensors, represented by gas sensors and biosensors, to detect the presence and concentration of a substance have been proposed. Among them, a field-effect transistor (hereinafter, referred to as FET) sensor is one which detects the presence/absence of a substance utilizing the gate function through adsorption of the substance, i.e., the field effect through which the adsorbed species affect the transistor.

As such an FET sensor, a sensor for a poison gas using a metal oxide semiconductor as the gate electrode is already practically used. A biosensor is also proposed in Japanese Patent Application Laid-Open No. S51-139289, which has a constitution wherein an inductor is formed on a gate surface, and a potential shift generated by the interaction between a substance to be detected and the inductor is caught as a gate potential shift.

Then, various studies have been conducted till now for enhancing the sensitivity of such an FET sensor.

For example, Japanese Patent Publication No. H04-60549 proposes a biosensor in which an inductor consists of a substrate comprised of a polymer compound with finely uneven shape, an LB (Langmuir-Blodgett) membrane formed on the substrate, and a biologically related substance such as an enzyme and an antibody immobilized on the LB membrane.

The above proposal recites that as compared with a flat substrate, the formation of unevenness on the substrate increases the surface concentration of the biologically related substance, and consequently, increases the contact area with a substance to be detected. Thus surface roughness of a substrate increases the sensitivity.

Japanese Patent Publication No. S60-26456 recites that the use as an inductor of single crystalline ultrafine particles of 1 nm to 12 nm in average size increases the sensitivity because the surface energy of the ultrafine particles is extremely high compared with the bulk, and proposes a method of manufacturing a sensor by fixing ultrafine particles of Sn oxide to a resin film on a gate insulator.

However, the uneven shape increasing the contact area of the substance and the inductor in Japanese Patent Publication No. H04-60549 as described above is a structure only of the substrate surface. That is, it is not a structure which effectively utilizes the substrate interior, and leaves room for improvement in view of further increasing the specific surface area.

Besides, only the unevenness with submicron scales is available, since that is formed by etching process, and consequently, the formed unevenness becomes ineffective for sensing of small species.

On the other hand, in Japanese Patent Publication No. S60-26456 as described above, the ultrafine particles are partially embedded in a resin film, so their surface area doesn't fully take part in the detection.

### SUMMARY OF THE INVENTION

The present invention has an object to provide a field-effect transistor and a highly sensitive sensor, and manufacturing methods of the same.

According to an aspect of the present invention, there is provided a field-effect transistor comprising: a semiconductor substrate, and a source region, a drain region and a gate region on the semiconductor substrate, wherein the gate region has a porous material having mesopores of which the walls contain microcrystals of tin oxide, and wherein the porous material provides at least one diffraction peak in an angular region corresponding to a structural periodicity of 1 nm or more in X-ray diffractometry.

The mesopores preferably have a size distribution determined by a nitrogen gas adsorption measurement, the size distribution has a single maximum value, and 60% or more of the mesopores have sizes within the range of from the maximum value plus 5 nm to the maximum value minus 5 nm.

The microcrystals preferably have an average crystal grain size of 6 nm or less.

The porous material is preferably in the shape of a film.

According to another aspect of the present invention, there is provided a method of manufacturing a field-effect transistor comprising a source region, a drain region and a gate region, comprising the steps of:

dissolving a tin compound and a surfactant in a solvent to prepare a reaction solution;

applying the reaction solution onto a region to be the gate region on a substrate;

holding the substrate in an atmosphere containing water vapor to fabricate a porous material precursor; and

removing the surfactant from the precursor to fabricate a porous material on the region to be the gate region.

The surfactant is preferably a nonionic surfactant.

The surfactant preferably contains an ethylene oxide chain.

The surfactant is preferably a block copolymer.

The step of holding the substrate in an atmosphere containing water vapor to fabricate a porous material precursor is preferably carried out at temperature of 100° C. or less.

The step of holding the substrate in an atmosphere containing water vapor to fabricate a porous material precursor is preferably carried out at relative humidity of 40% to 100%.

(According to a still another aspect of the present invention, there is provided a field-effect transistor comprising a source region, a drain region and a gate region, wherein the gate region has a porous material having mesopores the walls of which contain crystals of tin oxide.)

According to a further aspect of the present invention, there is provided a sensor comprising a field-effect transistor comprising a source region, a drain region and a gate region and a signal detection circuit connected to the field-effect transistor, wherein the gate region has a porous material having mesopores the walls of which contain crystals of tin oxide.

According to a further aspect of the present invention, there is provided a method of fabricating a sensor which comprises a field-effect transistor comprising a source region, a drain region and a gate region, and a signal detection circuit connected to the field-effect transistor, comprising the steps of:

dissolving a tin compound and a surfactant in a solvent to prepare a reaction solution;

applying the reaction solution onto a region to be the gate region on a substrate;

holding the substrate in an atmosphere containing water vapor to fabricate a porous material precursor;

removing the surfactant from the precursor to fabricate a porous material on the region to be the gate region; and

connecting the signal detection circuit to the source region and/or the drain region.

According to the present invention, a large amount of substances to be detected can be adsorbed on the gate region easily and uniformly in a short time.

A suitable embodiment of the present invention exhibits excellent semiconductor properties and also an excellent sensitivity as a sensor, with the porous material containing microcrystals on the inner wall surfaces (hereinafter, simply referred to as pore wall) of the mesopores.

### BRIEF DESCRIPTION OF THE DRAWINGS

FIG. 1 is an illustrative diagram showing one example of a sensor structure according to the present invention;

FIG. 2 is an illustrative diagram showing one example of a micropore structure of a porous material according to the present invention; and

FIG. 3 is a diagram showing a manufacturing process of a porous material according to the present invention.

### DESCRIPTION OF THE PREFERRED EMBODIMENTS

Then, preferred embodiments of the present invention will be illustrated in detail referring to the drawings.

(FET Sensor)

A gate region of an FET sensor of the present invention has a porous material with a regular mesoporous structure containing tin oxide microcrystals in the pore walls.

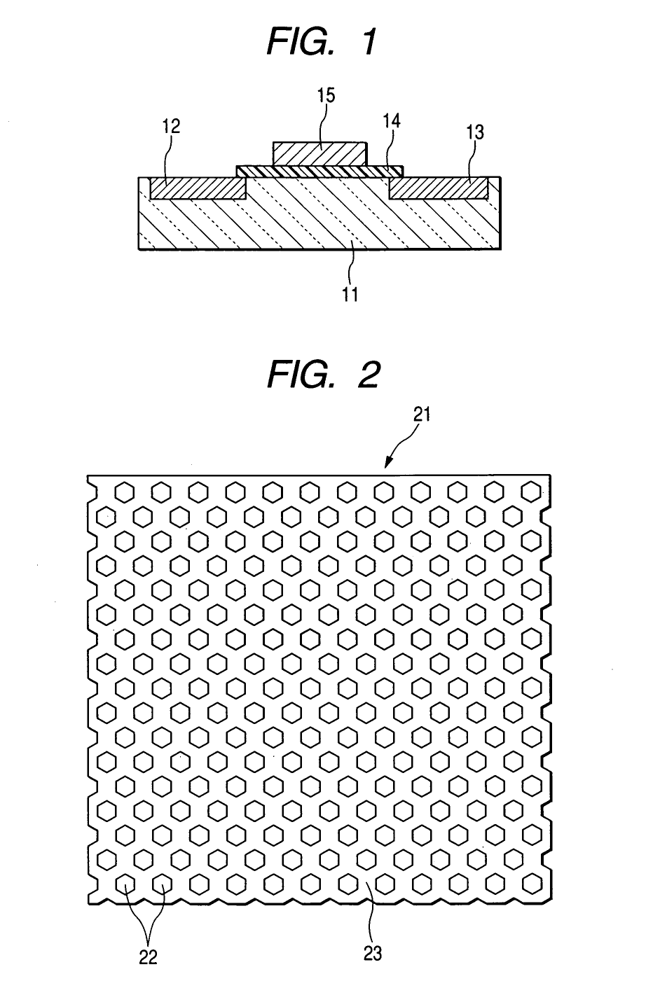

FIG. 1 is an illustrative diagram showing one example of a sensor structure according to the present invention. As in FIG. 1, the sensor of the present invention is formed of a source region 12, a drain region 13, a gate insulator 14 and a gate region 15 on a semiconductor substrate 11, and in the gate region the porous material is formed. The source region and the drain region are connected to electrodes and an electric signal detection circuit (not shown in figure), whereby a resistance shift between the source and the drain by a reaction of a detection object substance and the porous material can be measured.

In respect to a gate region used in the present invention, the entire of the gate region is desirably the porous material, but the gate region may have a constitution in which a part thereof is the porous material.

Active regions such as the source region, the drain region and a channel region of the present invention can be fabricated using any of a single crystalline semiconductor, a polycrystalline semiconductor, a microcrystalline semiconductor and an amorphous semiconductor. Constituent materials of the active region include, specifically, single crystalline silicon, polycrystalline silicon, microcrystalline silicon and amorphous silicon.

For promoting the adsorption/desorption reaction of a detection object substance, a heater may be installed on the substrate.

The sensor according to the present invention can be suitably used as a gas sensor, a biosensor, etc., but as long as it is a sensor which detects a substance by utilizing the gate function through adsorption/desorption of a substance, it is not limited to them, and can be suitably used for an ion sensor, a humidity sensor, a PH sensor, and the like.

Next, the porous material according to the present invention will be further illustrated.

Pores of the porous material according to the present invention are preferably mesopores.

The “mesopore” is based on the classification of IUPAC (International Union of Pure and Applied Chemistry), denoting that of 2 nm to 50 nm in pore size.

If macroporous materials with larger pores are used, the specific surface area of the entire porous material decreases, and the amount of adsorption may possibly decrease. By contrast, if microporous materials with smaller pores are used, rapid adsorption of a detection object substance may be difficult. Particularly, when biological substances are detected, they cannot be adsorbed in the micropores because many biological substances are larger than micropores.

However, hierarchical porous structure, that is, the combination of macropores and mesopores, can be employed to facilitate the adsorption of a substance from a solution, etc.

The porous material used in the present invention preferably has at least one diffraction peak in an angular region corresponding to the structural periodicity of 1 nm or more in X-ray diffractometry. Such a diffraction peak is observed for the porous materials having a regular mesoporous structure or those with randomly arranged uniform mesopores. The regular porous structure is, for example, that shown in FIG. 2. A two-dimensional hexagonal structure 21 is shown in FIG. 2, but the arrangement of mesopores 22 is not limited to this. Besides this, for example, a cubic structure, a three-dimensional hexagonal structure can be used. When the mesoporous material has a regular porous structure or consist of randomly arranged uniform mesopores, a detection object substance is adsorbed/desorbed easily and uniformly in the mesoporous material, allowing the fabrication of a sensor with a short equilibration time and fast response.

For the evaluation of the pore size distribution in a porous material, the adsorption isotherm measurement of a gas such as nitrogen is generally used, and the pore size distribution is calculated from the obtained adsorption isotherm by the analyzing method of Berret-Joyner-Halenda (BJH), etc.

Preferably, the pore size distribution of mesopores in a porous material used in the present invention determined by the BJH method from a nitrogen gas adsorption measurement has a single maximum value, and 60% or more of the mesopores have sizes within the range of from the maximum value plus 5 nm to the maximum value minus 5 nm.

In the case of using a porous material having a pore size distribution larger than this, problems sometimes occur that a detection object substance does not easily diffuse and penetrate inside the smaller pores, and that the interior of the larger pores, that does not take part in the detection, increases.

A molecular recognition material that reacts selectively with a detection object substance may be formed on the pore surfaces of the porous material. In living matter, for example, as combinations having mutual affinity are enzyme-substrate, antigen-antibody, DNA-DNA and the like. Therefore, in the case of a biological substance as the detection object substance, one member of a combination is formed as a molecular recognition site on the pore surfaces of a porous material, and then the other member substance of the combination can selectively be measured.

The pore size can be controlled by suitably selecting the surfactant described later. The pore size controllability has advantages as follows. One is the sieving effect. When substances not to be detected, larger in size than the object substance, are present in a test sample, they are excluded by the uniform pores. Another is the stabilization effect. When the detection object substance and the molecular recognition material described above are biological substances such as proteins, suitable control of the pore sizes in accordance with their sizes contributes to their stabilization.

A metal oxide exhibiting a good semiconductor properties is suitably used for the constitutional material of the porous material as denoted by numeral 23 in FIG. 2, and the porous material according to an embodiment of the present invention is characterized in that the pore walls thereof contain tin oxide, particularly, microcrystals of tin oxide. The crystal grain size of the tin oxide is preferably 12 nm or less. For further providing a high sensitive sensor, the correlation between the crystal size and the thickness of the space charge layer is important. Because the thickness of the space charge layer of tin oxide is approximately 3 nm, the crystal size (diameter) of tin oxide in the present invention is more preferably 6 nm or less. That is twice the thickness of the space charge layer.

The shape of a porous material is preferably a film. If the porous material is used as a form of aggregated particles, the interior of the particles does not take part in the sensing, and consequently, the sensitivity that depends on the specific surface area may not be high enough. Again, because the interparticle gap is not controlled, response speed would be a problem in the sensor.

(Method of Manufacturing FET Sensor)

Next, a method of manufacturing an FET sensor, according to an embodiment of the present invention, provided with a gate region of a tin oxide porous material in the shape of a film comprising a regular mesoporous structure and pore walls containing microcrystals, is illustrated.

The feature of the manufacturing method above lies in a method in which a tin oxide porous material is formed for a gate region of FET. So, conventional methods are applicable to the manufacturing method of other parts of the FET.

A common manufacturing method of FET can be used, for example, in which the steps include using a p-type silicon substance having an orientation (100), forming a source region and a drain region by diffusing or implanting an impurity, e.g., phosphorus to form a n-type semiconductor by the thermal diffusion method or the ion implantation method, and forming a gate insulator by heat-treating in a dry oxygen atmosphere.

Then, a tin oxide porous material is formed on the gate insulator.

Here, formation of a source region, a drain region, etc., other than the gate insulator may be done either before or after the formation of the tin oxide porous material on the gate insulator as long as the FET structure is finally formed. Any process can be used as long as a tin oxide porous material is formed on the gate insulator.

Next, a method of forming a tin oxide porous material will be illustrated in detail.

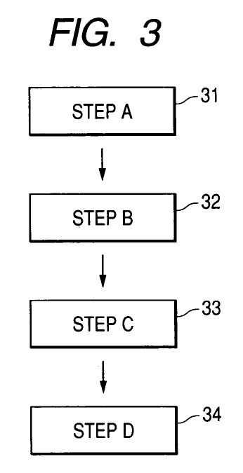

FIG. 3 is a process diagram showing a method of forming a tin oxide porous material in the present invention. In FIG. 3, the step A, 31, involves preparing a reactant solution by dissolving a tin compound and a surfactant in a solvent; the step B, 32, involves applying the reactant solution onto a gate insulator of a substrate; the step C, 33, involves holding the substrate in an atmosphere containing water vapor; and the step D, 34, involves removing the surfactant.

Through the steps A to C, a precursor film of the porous material, which has regions comprised of surfactant assembly, is formed on the gate insulator of the substrate. The surfactant assembly works as a template of the mesopores, and hollow mesopores are formed after the removal of the surfactant. Such a structure is formed by the formation of tin oxide around the surfactant self-assembly, micelles.

Holding the substrate in an atmosphere containing water vapor in the step C improves the structural regularity of the precursor film. Simultaneously, the water vapor induces crystallization of tin oxide soon after the exposure.

Further, through the step D, the surfactant is removed, and the porous material is formed.

Hereinafter, each step will be illustrated in detail.

(Step A: Preparation of the Reactant Solution)

In this step, a tin compound and a surfactant are dissolved in solvents to prepare a reactant solution.

The tin compound includes chlorides of tin such as stannous chloride and stannic chloride, and tin alkoxides such as tin isopropoxide and tin ethoxide, but are not limited to these.

The surfactant forms micelles and the micelles work as templates of mesopores. Nonionic surfactants are preferably used for the surfactant. Particularly, surfactants containing ethylene oxide chains is suitable. Such a surfactant includes triblock copolymers such as <HO(CH₂CH₂O)₂₀(CH₂CH(CH₃)O)₇₀(CH₂CH₂O)₂₀H>. The use of such block polymers with relatively long ethylene oxide chains tends to increase the thickness of the pore wall, which is preferable in the viewpoint of stability of the porous material.

When minuter mesopores are needed for the detection of small object substance, polyoxyethylene(10) dodecyl ether <C₁₂H₂₅(CH₂CH₂O)₁₀OH>, polyoxyethylene(10) tetradecyl ether <C₁₄H₂₉(CH₂CH₂O)₁₀OH>, polyoxyethylene (10) hexadecyl ether <C₁₆H₃₃(CH₂CH₂O)₁₀OH>, polyoxyethylene(10) stearyl ether <C₁₈H₃₇ (CH₂CH₂O)₁₀OH>, and the like can be used. In the case of these surfactants, the size of the mesopores decreases as the decrease of the alkyl chain length. However, the surfactant is not limited to these as long as the objective porous material can be formed.

For the solvent, an alcohol such as methanol or ethanol is suitable, and a mixture of, for example, alcohol/water is also usable, but it is not limited to these as long as it is a liquid and can dissolve the tin compound and the surfactant.

Further, an acid such as hydrochloric acid may optionally be added as a catalyst.

(Step B: Disposition of the Reaction Solution)

In this step, the reactant solution fabricated in step A is deposited on a gate insulator on the substrate.

As a method of depositing the reactant solution on the gate insulator, many coating methods such as casting, dip coating, spin coating and ink jet can be employed. The other methods, such as spray coating, pen lithography, can also be used. The method is not limited to these as long as the reactant solution can be deposited on the gate insulator.

Here, for selectively forming a tin oxide porous material on the gate insulator, either the reactant solution may be applied by masking an unnecessary region other than a gate region in step B. Alternatively, a tin oxide porous material precursor or a tin oxide porous material in the unnecessary region may be removed after step B, C or D.

The above step B is a process to deposit the reactant solution. After the step B and before step C, the reactant solution on the substrate is preferably dried once. For example, after step B, a drying step to dry the solvent at a temperature ranging from 25° C. to 50° C. and a humidity ranging from 10% to 30% is preferably performed, followed by performing step C.

(Step C: Holding of Substrate in Atmosphere Containing Water Vapor)

Then, a precursor of a porous material is formed by holding the substrate in an atmosphere containing water vapor.

The atmosphere containing water vapor in step C is preferably relative humidity of 40% to 100% and temperature of 100° C. or less. Even if out of these ranges, however, any conditions can be adopted as long as the objective porous material precursor can be formed.

This step improves the uniformity, that is the structural regularity of the precursor of the porous material. This process simultaneously induces the crystallization of tin oxide of the pore walls. Since the progress of crystallization of tin oxide depends on the condition of step C, the condition has to be optimized based on the objective crystallinity, etc.

(Step D: Removal of the Surfactant)

The removal of the surfactant can be performed using common methods. For example, calcination is a convenient method, in which high temperature promotes crystallization of the pore walls. Since high temperature disturbs the mesoporous structure along the crystallization of tin oxide, temperature for removing the surfactant should be optimized. When the substrate material cannot withstand such high temperature, extraction by a supercritical fluid, extraction by a solvent and the like can be used as the method for removing the surfactant. Besides these, there are various means such as ultraviolet irradiation and oxidative decomposition by ozone, and any methods can be used as long as they do not destroy the porous structure.

As illustrated above, through step A to step D, a film-shaped tin oxide porous material having a mesoporous structure and microcrystals in pore walls is formed on a gate insulator.

Hereinafter, the present invention will be illustrated in detail by way of examples, but is not limited to these examples, and materials, reaction conditions, etc., can optionally be changed within the range where sensors of similar structures can be obtained.

### EXAMPLE 1

Example 1 is an example wherein a gas sensor of FET type in which a tin oxide porous material thin film was formed on a gate insulator was fabricated, and used for detecting H₂ gas.

First, a silicon oxide film is formed on a p-type (100) silicon substrate by the thermal oxidation method, and is used for a gate insulator.

Next, stannic chloride anhydride of 2.9 g was added to ethanol of 10 g, and stirred for 30 min, and thereafter a triblock copolymer surfactant P-123<HO(CH_{2 CH}₂O)₂₀(CH₂CH(CH₃)O)₇₀(CH₂CH₂O)₂₀H)> of 1.0 g was dissolved therein, and further stirred for 30 min to obtain a reactant solution A.

Then, the reactant solution A was deposited on the gate insulator of the substrate by a dip coating method.

The substrate was moved into an environmental test chamber, and held. The temperature and the relative humidity in the environmental test chamber were controlled as follows. The substrate coated with the reactant solution A was first dried at 40° C. and 20% RH for 10 h, and then the temperature and the humidity were raised to 50° C. and 90% RH taking one hour, held there for five hours, and then returned again to 40° C. and 20% RH taking one hour.

Thereafter, the substrate was taken out from the environmental test chamber, and was put in a muffle furnace, whose temperature was raised to 300° C., and baked in air.

Through the steps above, a tin oxide porous material thin film was formed on the gate insulator.

SEM observations of the surface and the cross section of the thin film were conducted; in the surface view, a tube-shaped structure was observed; and in the cross section, a state of micropores arrayed in a honeycomb shape was confirmed.

Through X-ray diffractometry, a distinct diffraction peak assigned to two-dimensional hexagonal porous structure was observed at an angle corresponding to a lattice spacing of 4.9 nm. But, SEM observation, etc., revealed that the structure was actually a distorted hexagonal structure shrunk in the thickness direction.

A nitrogen gas adsorption measurement was conducted, and the pore distribution was determined by the BJH method. The result showed that the pores had a simple variance having a maximum at approximately 5.1 nm, and the distribution curve was included in the range of not less than 1 nm and not more than 10 nm. The specific surface area was 168 m²/g. Thus, the thin film was confirmed to be a porous material thin film having uniform mesopores and a large specific surface area.

Next, through a grazing incidence X-ray diffractometry of the thin film, a distinct peak assigned to Cassiterite was observed. That is, the formation of the microcrystals of tin oxide in the pore walls with retaining the mesopores was confirmed. Further, the average crystal size L was determined to be 2.7 nm by the Scherrer formula: L=0.9λ/B cos θ, using the value of full width of the half maximum of a diffraction peak in the region of 2θ=45° to 58°, B (rad), and a peak position 2θ. Hereinbefore, the formation of a porous material thin film having a regular mesoporous structure and pore walls containing microcrystals of tin oxide was confirmed.

Then, an unnecessary part of the gate insulator and tin oxide porous material thin film was removed by the lithography technique and the etching technique. Next, a source region and a drain region were formed using the lithography technique and the ion implanting method, and connected with a signal detection circuit not shown in figure.

By the above operations, a gas sensor of FET type in which the tin oxide porous material thin film was formed was fabricated.

Then, the performances of H₂ gas sensing were evaluated for the gas sensor according to this example and a conventional sensor. Here, the conventional sensor was fabricated using a tin oxide sintered body baked at 600° C. to 800° C., like commonly used sensors. The apparent area of a tin oxide layer of the conventional type sensor was set to be identical to that of the tin oxide layer of the sensor of this example.

The measurement was conducted in a flow system. First, synthetic air (nitrogen 80, oxygen 20%) was introduced. Thereafter, H₂ gas was mixed to the synthetic air and introduced while the concentration was varied. The resistance shifts of the sensors with the introduction of the gas were measured by measuring the current shifts between the sources and the drains. As the result, the sensor having a tin oxide porous material thin film according to this example exhibited a larger current shift by the introduction of H₂ gas than the conventional sensor, and could provide enough sensitivity even when the H₂ gas concentration was low.

From the above results in this example, it was shown that a highly sensitive gas sensor of FET type was fabricated by using a gate region having a tin oxide mesoporous material thin film whose pore walls contain microcrystals.

### EXAMPLE 2

Example 2 is an example wherein an FET biosensor in which a tin oxide porous material thin film was formed on a gate insulator was fabricated, and wherein the biosensor, in which biotin was further immobilized in the tin oxide porous material thin film as a molecular recognition material to detect avidin, was fabricated.

First, a source region and a drain region were formed on a silicon substrate by the ion implantation and the heat treatment. Then, a gate insulator was formed on the channel region between the source region and the drain region.

Next, stannic chloride anhydride of 2.9 g was added to ethanol of 10 g, and stirred for 30 min, and thereafter a triblock copolymer surfactant F-127 <HO(CH_{2 CH}₂O)₁₀₆(CH₂CH(CH₃)O)₇₀(CH₂CH₂O)₁₀₆H)> of 1.0 g was dissolved therein, and further stirred for 30 min to obtain a reactant solution B.

Then, the reactant solution B was deposited on the gate insulator of the substrate by a spin coating method.

The substrate was moved into an environmental test chamber, and held. The temperature and the relative humidity in the environmental test chamber were controlled as follows. The substrate coated with the reactant solution A was first dried at 40° C. and 20% RH for 10 h, and then the temperature and the humidity were raised to 50° C. and 90% RH taking one hour, held there for five hours, and then returned again to 40° C. and 20% RH taking one hour.

Thereafter, the substrate was taken out from the environmental test chamber, and was put in a muffle furnace, whose temperature was raised to 300° C., and baked in air.

Through the steps above, a tin oxide porous material thin film was formed on the gate insulator.

SEM observations of the surface and the cross section of the thin film were conducted. Both in the surface and cross sectional views, mesoporous structure consist of spherical pores was observed.

Through X-ray diffractometry, a distinct diffraction peak assigned to cubic porous structure was observed at an angle corresponding to a lattice spacing of 5.8 nm. But, the SEM observation, etc., revealed that the structure was actually a distorted cubic structure shrunk in the thickness direction.

A nitrogen gas adsorption measurement was conducted, and the pore distribution was determined by the BJH method. The result showed that the pores had a simple variance having a maximum at approximately 7.0 nm, and the distribution curve was included in the range of not less than 2.0 nm and not more than 12.0 nm. The specific surface area was 201 m²/g. Thus, the thin film was confirmed to be a porous material thin film having uniform mesopores and a large specific surface area.

Next, through a grazing incidence X-ray diffractometry of the thin film, a distinct peak assigned to Cassiterite was observed as in Example 1. That is, the formation of the microcrystals of tin oxide in the pore walls with retaining the mesopores was confirmed. Further, the average crystal size L was determined to be 2.8 nm.

Hereinbefore, the formation of a porous material thin film having a regular mesoporous structure and pore walls containing microcrystals of tin oxide was confirmed.

Then, biotin was immobilized as a molecular recognition material by immersing the fabricated tin oxide porous material thin film in an ethanol solution of biotin silane. A method of immobilizing biotin silane on a metal oxide is disclosed in Japanese Patent Application Laid-Open No. H07-260790, and is applicable to the tin oxide porous material thin film as in this example.

Then, an unnecessary part of the gate insulator and tin oxide porous material thin film was removed by the lithography technique and the etching technique. Then, the source region and/or the drain region were/was connected with a signal detection circuit.

By the above operations, an FET biosensor in which the tin oxide porous material thin film was formed was fabricated.

Then, the sensing performances were evaluated for the detection of avidin using the biosensor according to this example and a conventional sensor. Here, the conventional sensor was fabricated using a tin oxide sintered body baked at 600° C. to 800° C., as in Example 1, after the biotin immobilizing treatment like the above. The apparent area of a tin oxide layer of the conventional type sensor was set to be identical to that of the tin oxide layer of the sensor of this example.

The measurement was conducted in a solution. First, the sensor was immersed in a phosphoric acid buffer solution (pH 7.4). Thereafter, an avidin solution was added in the buffer solution while the avidin concentration was gradually increased. The resistance shifts of the sensors with the introduction of the solution were measured by measuring the current shifts between the sources and the drains. As the result, the biosensor having the tin oxide porous material thin film according to this example exhibited a larger current shift by the introduction of the avidin solution than the conventional sensor, and could provide enough sensitivity even when the avidin concentration was low.

From the above results, in this example, it was shown that a highly sensitive FET biosensor was fabricated by using a gate region a tin oxide mesoporous material thin film whose pore walls contain microcrystals.

This application claims priority from Japanese Patent Application No. 2004-271804 filed Sep. 17, 2004, which is hereby incorporated by reference herein.

What is claimed is:

1. A field-effect transistor comprising: a semiconductor substrate, and a source region, a drain region and a gate region on the semiconductor substrate, wherein the gate region has a porous material having mesopores of which the walls contain microcrystals of tin oxide, and wherein the porous material provides at least one diffraction peak in an angular region corresponding to a structural periodicity of 1 nm or more in X-ray diffractometry.

2. The field-effect transistor according to claim 1, wherein the mesopores have a size distribution determined by a nitrogen gas adsorption measurement, the size distribution has a single maximum value, and 60% or more of the mesopores have sizes within the range of from the maximum value plus 5 nm to the maximum value minus 5 nm.

3. The field-effect transistor according to claim 1, wherein the microcrystals have an average crystal grain size of 6 nm or less.

4. The field-effect transistor according to claim 1, wherein the porous material is in the shape of a film.

5. A method of manufacturing a field-effect transistor comprising a source region, a drain region and a gate region, comprising the steps of:
dissolving a tin compound and a surfactant in a solvent to prepare a reaction solution;
applying the reaction solution onto a region to be the gate region on a substrate;
holding the substrate in an atmosphere containing water vapor to fabricate a porous material precursor; and
removing the surfactant from the precursor to fabricate a porous material on the region to be the gate region.

6. The method of manufacturing a field-effect transistor according to claim 5, wherein the surfactant is a nonionic surfactant.

7. The method of manufacturing a field-effect transistor according to claim 5, wherein the surfactant contains an ethylene oxide chain.

8. The method of manufacturing a field-effect transistor according to claim 5, wherein the surfactant is a block copolymer.

9. The method of manufacturing a field-effect transistor according to claim 5, wherein the step of holding the substrate in an atmosphere containing water vapor to fabricate a porous material precursor is carried out at temperature of 100° C. or less.

10. The method of manufacturing a field-effect transistor according to claim 5, wherein the step of holding the substrate in an atmosphere containing water vapor to fabricate a porous material precursor is carried out at a relative humidity of 40% to 100%.

11. A field-effect transistor comprising a source region, a drain region and a gate region, wherein the gate region has a porous material having mesopores the walls of which contain crystals of tin oxide.

12. A sensor comprising a field-effect transistor comprising a source region, a drain region and a gate region and a signal detection circuit connected to the field-effect transistor, wherein the gate region has a porous material having mesopores the walls of which contain crystals of tin oxide.

13. A method of fabricating a sensor which comprises a field-effect transistor comprising a source region, a drain region and a gate region, and a signal detection circuit connected to the field-effect transistor, comprising the steps of:
dissolving a tin compound and a surfactant in a solvent to prepare a reaction solution;
applying the reaction solution onto a region to be the gate region on a substrate;
holding the substrate in an atmosphere containing water vapor to fabricate a porous material precursor;
removing the surfactant from the precursor to fabricate a porous material on the region to be the gate region; and
connecting the signal detection circuit to the source region and/or the drain region.
